(19) United States
(12) Patent Application Publication
(10) Pub. No.: US 2026/0337756 A1
(43) Pub. Date: Oct. 29, 2026

(54) METHOD FOR MANUFACTURING SPUTTERING TARGET AND METHOD FOR MANUFACTURING PEROVSKITE THIN FILM USING THE SPUTTERING TARGET

(71) Applicants: Hyundai Motor Company, Seoul (KR); Kia Corporation, Seoul (KR)

(72) Inventors: Byunghong Lee, Hwaseong-si (KR); Rira Kang, Hwaseong-si (KR); So Yeon Ju, Hwaseong-si (KR)

(73) Assignees: Hyundai Motor Company, Seoul (KR); Kia Corporation, Seoul (KR)

(21) Appl. No.: 19/330,352

(22) Filed: Sep. 16, 2025

(30) Foreign Application Priority Data
Apr. 22, 2025 (KR) 10-2025-0052290

(51) Int. Cl. C23C 14/34; C23C 14/08; C23C 14/35

(52) U.S. Cl. CPC C23C 14/3414; C23C 14/083; C23C 14/35

(57) ABSTRACT

The present disclosure relates to a method for manufacturing a sputtering target and method for manufacturing a perovskite thin film using the same. According to one embodiment of the present disclosure, a method for manufacturing a sputtering target is provided, comprising preparing a precursor solution including a metal halide, an organic halide, and a solvent, preparing perovskite crystals by mixing the precursor solution with an antisolvent, and sintering the perovskite crystals.

### CROSS-REFERENCE TO RELATED APPLICATION

This present application claims the benefit of priority to Korean Patent Application No. 10-2025-0052290, filed on Apr. 22, 2025, in the Korean Intellectual Property Office, the entire disclosure of which is incorporated herein by reference in its entirety.

### FIELD

The present disclosure relates to a method for manufacturing a sputtering target and a method for manufacturing a perovskite thin film using the sputtering target.

### BACKGROUND

Perovskite solar cells are attracting attention as a promising technology for next-generation solar energy conversion, primarily due to their high efficiency coupled with comparatively low manufacturing costs. The organic-inorganic hybrid perovskite materials are particularly noteworthy for their exceptional photoelectric properties, compatibility with flexible substrates, and lightweight characteristics. These attributes position perovskite materials as a viable option for the development of advanced photonic devices. Recent advancements in this field have resulted in remarkable achievements, with reported photoelectric conversion efficiencies reaching as high as 25%, indicating a substantial stride toward commercial viability. Nevertheless, several critical challenges must be surmounted to facilitate the successful commercialization of perovskite solar cells. These challenges include the enhancement of operational stability under various environmental conditions such as light exposure, thermal fluctuations, and moisture ingress. Furthermore, there is an essential need to improve charge transfer rates and to minimize the presence of toxic substances in the materials used. Additionally, the development of cost-effective methods for the large-scale production of perovskite thin films remains a pivotal area of research. Ongoing studies are actively addressing these challenges, underscoring the dynamic nature of this field and its potential for transforming the solar energy landscape.

Perovskite thin films are predominantly fabricated using solution-based techniques that rely on perovskite precursor solutions. However, the inherent sensitivity of these solution processes to a multitude of variables poses significant challenges in achieving films of consistent quality. One such challenge arises from the frequent use of toxic solvents within the precursor solutions, which complicates the maintenance of uniform quality throughout large-scale production. Additionally, the complexity of the production methodology often leads to the development of pores within the films, which can compromise their structural integrity. Moreover, non-uniformity in grain size and distribution adversely affects charge transport properties, resulting in diminished efficiency and performance of the perovskite materials. Consequently, improving the consistency and quality of perovskite thin films remains important for advancing their applications in photovoltaic and optoelectronic devices.

Research aimed at developing alternative technologies for the formation of perovskite thin films—strategies that could mitigate or eliminate the challenges associated with traditional solution processes—is still in its infancy. Thus, there is a need for manufacturing high-quality perovskite thin films with high stability and reproducibility over large areas.

### SUMMARY

The present disclosure is directed to providing a method for manufacturing a high-purity sputtering target using organic-inorganic hybrid perovskite crystals.

The present disclosure is further directed to providing a method for manufacturing high-quality perovskite thin films with high stability and reproducibility over large areas.

One aspect of the present disclosure provides a method for manufacturing a sputtering target, comprising preparing a precursor solution including a metal halide, an organic halide, and a solvent, preparing perovskite crystals by mixing the precursor solution with an antisolvent, and sintering the perovskite crystals.

In one embodiment, the concentration of the metal halide or organic halide in the precursor solution is 0.9 M or more.

In one embodiment, the concentration of the metal halide or organic halide in the precursor solution is 1.1 M or more.

In one embodiment, the metal halide comprises one or more divalent metal cations selected from Pb²⁺, Sn²⁺, Bi²⁺, Ge²⁺, Mn²⁺, or Cu²⁺.

In one embodiment, the organic halide comprises one or more monovalent cations selected from methylammonium or formamidinium.

In one embodiment, the solvent of the precursor solution has a volume of 15 mL to 500 mL.

In one embodiment, the preparing a precursor solution comprises preparing a precursor solution by mixing a metal halide, an organic halide, and a solvent having high solubility for the metal halide and the organic halide, and heat-treating the precursor solution.

In one embodiment, the antisolvent comprises one or more solvents selected from chlorobenzene, dichlorobenzene, chloroform, dichloroethylene, trichloroethylene, toluene, or xylene.

In one embodiment, the perovskite crystals is crystalline aggregates having an average diameter of 1 inch or more.

In one embodiment, the perovskite crystals has diffraction peaks appearing at scattering vectors (Q, nm⁻¹) corresponding to (110) and (220) planes in grazing incidence wide angle X-ray scattering (GIWAXS) analysis results using Cu Kα X-ray wavelength.

In one embodiment, the perovskite crystals satisfies Inequality 1 in grazing incidence wide angle X-ray scattering (GIWAXS) analysis results using Cu Kα X-ray wavelength.

I₁/I₂<0.5 [Inequality 1]

In Inequality 1, I₁ is the peak intensity at a scattering vector of 9±0.5 nm⁻¹, and I₂ is the peak intensity at a scattering vector of 20.0±0.5 nm⁻¹.

Another aspect of the present disclosure provides a sputtering target manufactured by the above-described method for manufacturing a sputtering target.

Still another aspect of the present disclosure provides a method for manufacturing a perovskite thin film, comprising performing a sputtering process using the above-described sputtering target.

In one embodiment, the sputtering process is performed under power of 4 W to 40 W.

In one embodiment, the sputtering process is performed for 600 seconds to 45,000 seconds.

Embodiments of the present disclosure provides a method for manufacturing a high-purity sputtering target using organic-inorganic hybrid perovskite crystals.

In addition, a method for manufacturing a perovskite thin film according to embodiments of the present disclosure enables the formation of high-quality perovskite thin films with high stability and reproducibility over large areas, by using the sputtering target manufactured as described above.

### BRIEF DESCRIPTION OF THE DRAWINGS

The foregoing and other aspects, as well as the following detailed description of the embodiments, should be better understood when read in conjunction with the accompanying drawings. However, the present disclosure is not intended to be limited to the details shown in the drawings, and various modifications and structural changes is made therein without departing from the spirit of the present disclosure and within the scope and range of equivalents of the claims. Like reference numbers and designations in the various drawings indicate like elements.

FIG. 1 is a figure showing GIWAXS analysis results of perovskite crystals prepared in Example 1.

FIG. 2 is a figure showing a sputtering target manufactured in Example 1.

FIG. 3 is a figure showing XRD analysis results of a thin film formed according to Experimental Example 3.

FIG. 4, FIG. 5, and FIG. 6 are images showing thin films formed according to a sputtering process of Experimental Example 4. FIG. 4 is a figure showing thin films formed according to a sputtering process performed under various power and time conditions. FIG. 5 is a figure showing thin films formed according to a sputtering process performed under various time conditions (600 to 7,200 seconds). FIG. 6 is a figure showing thin films formed according to a sputtering process performed under other time conditions (4,800 to 43,200 seconds).

### DETAILED DESCRIPTION

Embodiments described in the present specification can be modified into various other forms, and the technology according to exemplary embodiments is not limited to the embodiments described below. The exemplary embodiments are provided to make the description of the present disclosure thorough and to fully convey the scope of the present disclosure to those skilled in the art.

Singular forms “a,” “an,” and “the” used in the specification and the appended claims are intended to include plural referents unless the context clearly dictates otherwise.

In addition, numerical ranges used in this specification includes the lower limit and upper limit and all values within the range, increments logically derived from the form and width of the defined range, all doubly limited values, and all possible combinations of upper and lower limits of numerical ranges limited in different forms. Unless specifically defined in this specification, values outside the defined numerical ranges that may occur due to experimental error or rounding off of values are also included within the defined numerical ranges.

Furthermore, reference throughout the specification to “including” or “comprising” a constituent element means that, unless specifically stated to the contrary, other constituent elements are not excluded and is included.

When a layer, film, area, or plate or the like is referred to as being “on” another layer, area, or plate, it is directly on the other layer, film, area, or plate, or intervening layers, films, areas, or plates is present therebetween.

“Halide” as used in this specification refers to a compound including one or more halogen ions selected from fluoride ions, chloride ions, bromide ions, or iodide ions.

Grazing incidence wide angle X-ray scattering (GIWAXS) measurements as used in this specification are performed using Cu Kα X-rays. The measurements are conducted by rotating at intervals of 0.1° within an incident angle range of 0.1° to 1.0°, and diffraction patterns are collected using a two-dimensional detector. For example, GIWAXS measurements is performed using Rigaku SmartLab 9 kW X-ray diffraction equipment, but the present disclosure is not limited thereto.

The solar cell currently reported to have the world's highest efficiency was manufactured using a solution process using spin coating, but this technology has only been demonstrated on small areas of 0.1 cm² or less. Therefore, to enable the mass production and commercialization of perovskite solar cells, it is necessary to develop new large-area technologies that can replace existing solution-based processes.

Vacuum deposition technology is attracting attention as a promising alternative for addressing these issues. Vacuum deposition is a method of depositing materials on substrates by vaporizing them in a vacuum state, providing high precision and reproducibility. Among vacuum deposition methods, thermal evaporation not only enables the formation of high-purity perovskite thin films, but also allows precise control over perovskite composition through co-deposition using various source materials. However, this technique has several drawbacks, including material stability issues caused by high-temperature processing, thermal stress, reduced crystallinity, difficulty in achieving uniform thin film thickness, material loss, and complexity in process control.

In contrast, sputtering processes have the advantage of being capable of performing processes at low temperatures, in addition to the advantages of thermal evaporation. In view of this, the inventors of the present disclosure conducted in-depth research focused on the development of high-purity targets suitable for sputtering processes, with the aim of enabling large-area fabrication and commercialization of perovskite solar cells.

Organic-inorganic hybrid perovskite materials, which are next-generation materials with various strengths, can be deposited through sputtering processes. However, due to differences in properties between organic and inorganic components, achieving high-quality deposition has been limited. In particular, since sputtering processes involve high-energy particles, it is believed that heat-sensitive organic materials easily decompose at elevated temperatures, leading to thermal damage during deposition.

After repeated research, the inventors of the present disclosure confirmed that the use of sputtering targets manufactured from organic-inorganic hybrid perovskite crystals enables the formation of high-quality perovskite thin film with high stability and reproducibility over large areas, and thus completed the present disclosure.

A method for manufacturing a sputtering target according to one embodiment of the present disclosure includes preparing a precursor solution including a metal halide, an organic halide, and a solvent (S1), preparing perovskite crystals by mixing the precursor solution with an antisolvent (S2), and sintering the perovskite crystals (S3).

According to the method, by manufacturing a sputtering target based on perovskite crystals manufactured using an antisolvent, a high-purity target with low impurity content is obtained. Manufacturing organic-inorganic hybrid perovskite thin films through sputtering processes using high-purity targets may greatly reduce thermal damage to organic materials compared to existing methods, enabling the formation of high-quality thin films. Furthermore, by forming perovskite thin films using vacuum deposition techniques rather than solution processes such as spin coating, high-quality thin films is formed over large areas.

S1 includes preparing a precursor solution including a metal halide, an organic halide, and a solvent. The precursor solution includes an organic halide together with a metal halide, thereby enabling the manufacture of sputtering targets for forming organic-inorganic hybrid perovskite thin films. Here, the solvent included in the precursor solution of S1 has high solubility for metal halides and organic halides, and is referred to as a “good solvent” to distinguish it from the antisolvent to be described below.

In one embodiment of the present disclosure, a precursor solution including a metal halide, an organic halide, and a good solvent, wherein the concentration of the metal halide or organic halide is 0.9 M or more, is provided. The metal halide and organic halide dissolved in the precursor solution contact the antisolvent, causing a crystallization process. At this time, the yield and purity of perovskite crystals may vary depending on the concentration of the precursor solution. When the metal halide or organic halide is dissolved in the precursor solution at a concentration of 0.9 M or more, the yield and purity of perovskite crystals is high. By manufacturing a sputtering target based on such perovskite crystals, a high-purity target with low impurity content is obtained. The upper limit of the concentration is 5 M or less, 4 M or less, or 2 M or less.

In a preferred embodiment, the concentration of the metal halide or organic halide in the precursor solution is 1.1 M or more. In various exemplary embodiments, the concentration of the metal halide or organic halide is 1.1 M to 5 M, 1.1 M to 4 M, 1.1 M to 2 M, 1.1 M to 1.6 M, or 1.2 M to 1.5 M. When the metal halide or organic halide is dissolved in the precursor solution at concentrations within the above range, the yield and purity of perovskite crystals is significantly improved.

In a preferred embodiment, the respective concentrations of the metal halide and the organic halide may both fall within the concentration ranges described above.

The metal halide and organic halide is included in the precursor solution in a molar ratio of 1:0.5 to 1:1.5. In various exemplary embodiments, the metal halide and organic halide is included in a molar ratio of 1:0.8 to 1:1.2. The metal halide and organic halide is dissolved together in the good solvent within the above molar ratio range, and subsequently crystallized by the antisolvent to form perovskite crystals.

The metal halide is a compound containing divalent metal cations. In various exemplary embodiments, the metal halide comprises one or more divalent metal cations selected from Pb²⁺, Sn²⁺, Bi²⁺, Ge²⁺, Mn²⁺, or Cu²⁺.

The organic halide comprises one or two monovalent cations selected from the group consisting of methylammonium and formamidinium.

The types of cations contained in the metal halide and organic halide are described only to explain the present disclosure in detail, and the present disclosure is not limited thereto. Accordingly, the metal halide and organic halide is any that can be dissolved in the precursor solution and then crystallized to generate perovskite crystals.

In one embodiment, the good solvent of the precursor solution has a volume of 15 mL to 500 mL. The yield and purity of perovskite crystals may vary depending on the volume of the good solvent of the precursor solution. When the volume of the good solvent satisfies the above range, the yield and purity of perovskite crystals is high. By manufacturing a sputtering target based on such perovskite crystals, a high-purity target with low impurity content is obtained. The good solvent of the precursor solution has a volume of 15 mL to 400 mL, 15 mL to 300 mL, 15 mL to 200 mL, or 15 mL to 100 mL.

In a preferred embodiment, the good solvent of the precursor solution has a volume of 30 mL to 500 mL. In various exemplary embodiments, the volume of the good solvent is 30 mL or more, 35 mL or more, 500 mL or less, 400 mL or less, 300 mL or less, 200 mL or less, 100 mL or less, 80 mL or less, or intermediate values of the above figures. For example, the volume of the good solvent is 30 mL to 400 mL, 30 mL to 300 mL, 35 mL to 200 mL, 35 mL to 100 mL, or 35 mL to 80 mL. When the volume of the good solvent satisfies the above range, the yield and purity of perovskite crystals is improved.

In a preferred embodiment, the concentration of the metal halide or organic halide in the precursor solution satisfies the range described above while the volume of the good solvent satisfies the range described above. When both are satisfied, the yield and purity of perovskite crystals is significantly improved.

The good solvent of the precursor solution is used without limitation as long as it can easily dissolve the metal halide and organic halide. For example, the good solvent is one or more solvents selected from gamma-butyrolactone, dimethylformamide (DMF), dimethylsulfoxide (DMSO), dimethylacetamide, N-methylpyrrolidone, N-methyl-2-pyridine, pyridine, or aniline.

S1 includes preparing a precursor solution by mixing a metal halide, an organic halide, and a good solvent, and heat-treating the precursor solution. Here, the heat treatment is for completely dissolving and reacting the metal halide and organic halide in the good solvent. The heat treatment is performed at a temperature of 80 °C to 120 °C or 90 °C to 120 °C, and considering yield and purity, may preferably be performed at a temperature of 95 °C to 105 °C. The heat treatment is performed, for example, while stirring for 10 minutes to 60 minutes. However, the specific method and time of heat treatment may vary depending on the specific substances of the metal halide, organic halide, and good solvent used, and the specific method is not particularly limited to the above.

S1 may further include filtering the heat-treated precursor solution. Here, the filtering is performed to remove residual impurities following the reaction between the metal halide and organic halide and to reduce defects in the resulting perovskite crystals. Such filtering processes is performed using commonly used filtering methods such as syringe filters and membrane filtration.

S2 includes preparing perovskite crystals by mixing the precursor solution with an antisolvent. The metal halide and organic halide dissolved in the precursor solution contact the antisolvent, causing a crystallization process.

In S2, the antisolvent is used without limitation as long as it has low solubility for each of the metal halide and organic halide, allowing the metal halide and organic halide to crystallize when the precursor solution and antisolvent contact each other. For example, the antisolvent comprises one or more solvents selected from chlorobenzene, dichlorobenzene, chloroform, dichloroethylene, trichloroethylene, toluene, or xylene. These antisolvents is advantageous for obtaining the perovskite crystals and may result in higher yield and purity of the perovskite crystals compared to other solvents. Considering yield and purity, the antisolvent may preferably be chlorobenzene.

In S2, the perovskite crystals is a single grain or a crystalline aggregate formed by the agglomeration of multiple grains. For example, the perovskite crystals is crystalline aggregates formed by the agglomeration of multiple grains, and is crystalline aggregates having an average size of 1 inch or more. In various exemplary embodiments, the perovskite crystals has a size of 1 inch to 5 inches or 1 inch to 3 inches.

Here, the average size of a grain or crystalline aggregate refers to the average diameter in the case of a spherical shape, and the average major axis length in the case of a non-spherical shape. The average size of crystal grains is measured using a particle size analyzer (PSA), and in the case of sufficiently large crystalline aggregates, is measured visually. “Average size” refers to D50, and D50 is the particle size corresponding to 50% cumulative volume in a particle size distribution measured by, for example, laser diffraction, calculated from the smaller-particle end of the distribution.

In S2, the perovskite crystals is single crystals. In various exemplary embodiments, the perovskite crystals has diffraction peaks appearing at scattering vectors (Q, nm⁻¹) corresponding to the (110) and (220) planes in grazing incidence wide angle X-ray scattering (GIWAXS) analysis results using Cu Kα X-ray radiation.

Among the diffraction peaks appearing in the range of 0 to 40 nm⁻¹, the diffraction peak corresponding to either the (110) or (220) plane has the highest scattering intensity, and the diffraction peak corresponding to the other of the (110) or (220) planes has the second-highest scattering intensity

Hereinafter, the meaning of peaks appearing in GIWAXS analysis results will be described using, as an example, the case in which perovskite crystals contain Pb. However, this is merely one embodiment, and the present disclosure is not limited thereto.

The (110) plane peak may appear at a scattering vector of 10±0.5 nm⁻¹, and the (220) plane peak may appear at a scattering vector of 20±0.5 nm⁻¹.

The peak appearing at the scattering vector of 10±0.5 nm⁻¹ and the peak appearing at the scattering vector of 20±0.5 nm⁻¹ correspond to α-phase peaks of the perovskite crystals. The α-phase peaks represent hexagonal perovskite crystals, and the higher the intensity of the α-phase peaks, the higher the crystallinity of the perovskite crystals.

The peak appearing at the scattering vector of 9±0.5 nm⁻¹ corresponds to a lead iodide (PbI₂) peak included in the perovskite crystals. The perovskite crystals includes lead halides that failed to crystallize or lead halides formed by the decomposition of perovskites due to environmental exposure. Accordingly, a lower intensity of the peak appearing at the scattering vector of 9±0.5 nm⁻¹ indicates less lead iodide impurity, which is interpreted as higher crystallinity of the perovskite crystals.

The perovskite crystals satisfies Inequality 1 in grazing incidence wide angle X-ray scattering (GIWAXS) analysis results using Cu Kα X-ray radiation.

I₁/I₂<0.5 [Inequality 1]

In Inequality 1, I₁ is the peak intensity at a scattering vector of 9±0.5 nm⁻¹, and I₂ is the peak intensity at a scattering vector of 20.0±0.5 nm⁻¹.

The ratio I₁/I₂ of I₁ to I₂ is 0.5 or less, 0.45 or less, 0.35 or less, 0.25 or less, 0.15 or less, 0.1 or less, or 0.01 or less, and preferably is 0. When I₁/I₂ satisfies the above range, a greater amount of α-phase perovskite crystals is included in the crystals, and the crystallinity of the perovskite crystals may increase, thereby significantly increasing device efficiency and stability.

S2 includes adding an antisolvent to the precursor solution, and drying the precursor solution to which the antisolvent has been added. The drying process may vary depending on the specific substances of the metal halide, organic halide, good solvent, and antisolvent used. For example, the drying of the precursor solution to which the antisolvent has been added is performed at a temperature of 120 °C to 200 °C or 140 °C to 180 °C. The drying process is performed for 5 hours to 20 hours or 10 hours to 15 hours, but is not particularly limited thereto.

The perovskite crystals prepared in S2 is obtained using commonly used filtering methods such as syringe filters, membrane filtration, and reduced pressure filters. As the perovskite crystals prepared in S2 may further include the good solvent and the antisolvent, the perovskite crystals is obtained by filtering out the good solvent and the antisolvent. The perovskite crystals obtained through the filtering may further undergo a drying process to additionally remove the good solvent, the antisolvent, and impurities from the crystal surface.

S3 includes sintering the perovskite crystals. A high-purity sputtering target is manufactured by sintering the high-purity perovskite crystals, and high-quality perovskite thin films is manufactured using such high-purity sputtering targets.

The sintering the perovskite crystals includes compressing at a pressure of 200 bar to 1,000 bar, and sintering at 50 °C to 100 °C.

The compression process is performed under a pressure of 200 bar to 500 bar or 250 bar to 350 bar, and the compression time is 0.1 minutes to 20 minutes or 0.5 minutes to 5 minutes, but is not particularly limited thereto.

The sintering process is performed at a temperature of 50 °C to 80 °C or 50 °C to 70 °C, and the sintering time is 0.1 minutes to 20 minutes or 0.5 minutes to 5 minutes, but is not particularly limited thereto.

The present disclosure may also provide a sputtering target manufactured by the method for manufacturing a sputtering target as described above. The sputtering target has the advantage of low impurity content, as it is manufactured according to the above-described method.

Further, the present disclosure provides a method for manufacturing a perovskite thin film, the method comprising performing a sputtering process using the sputtering target described above. The manufactured perovskite thin film has the advantage of being stable and having high reproducibility and quality, as they are manufactured by the sputtering process using high-purity sputtering targets as described above.

The method for manufacturing a perovskite thin film includes placing the sputtering target on a deposition target, and performing a sputtering process to form a perovskite thin film on the deposition target. When manufacturing perovskite thin films to be applied to solar cells, the deposition target is an electron transport layer or a hole transport layer.

The sputtering process is performed under power of 4 W to 40 W. In various exemplary embodiments, the sputtering process is performed under power of 5 W to 30 W or 5 W to 25 W. When the power range satisfies the above range, thin films having the stability and thickness that the present disclosure aims to implement is manufactured. Thus, when satisfying the above range, a phenomenon of sputtering targets manufactured from perovskite crystals decomposing during the deposition process is significantly suppressed.

The sputtering process is performed under a pressure of 0.1 mTorr to 10 mTorr or 1 mTorr to 5 mTorr.

The sputtering process is performed under a flow rate of 5 sccm to 50 sccm or 10 sccm to 30 sccm. Here, inert gases such as argon and nitrogen is used.

The sputtering process is performed for 600 seconds to 45,000 seconds. When the process time satisfies the above range, thin films having the stability and thickness that the present disclosure aims to implement is manufactured.

The perovskite thin films formed by the sputtering process has a thickness of 100 nm or more, 120 nm or more, 140 nm or more, 500 nm or less, 400 nm or less, 300 nm or less, 250 nm or less, or intermediate values of the above figures. For example, the thickness of the perovskite thin films is 100 nm to 500 nm, 120 nm to 400 nm, 140 nm to 300 nm, or 140 nm to 250 nm.

One embodiment of the present disclosure provides a perovskite solar cell including a light absorption layer including a perovskite thin film manufactured as described above. The perovskite solar cell has the advantage of being suitable for large-area implementation and having improved efficiency due to the inclusion of such a light absorption layer.

Hereinafter, examples and experimental examples will be specifically illustrated and described below. However, the following examples and experimental examples are only illustrative, and the technology described in this specification is not limited thereto.

### Example 1

### Preparing Perovskite Crystals

3.1794 g of methylammonium iodide (MAI) and 9.2202 g of lead iodide (PbI₂) were each dissolved at 1.0 M concentration in 20 mL of gamma-butyrolactone (GBL) as a good solvent to prepare a precursor solution. The precursor solution was placed in a 50 mL vial and heat-treated at 90 °C for 30 minutes while stirring at 250 rpm using a magnetic stirrer and hot plate. The precursor solution was filtered into a 200 mL vial using a syringe filter, then 15 mL of chlorobenzene (CB) as an antisolvent was added, and the mixture was dried at 150 °C for 12 hours. The resulting crystals were washed with diethyl ether, filtered, and dried at 50 °C for 12 hours to yield perovskite crystals (yield: 27.4%). The prepared perovskite crystals were crystalline aggregates having an average size of 1.5 inches.

### Manufacturing Sputtering Target

The perovskite crystals prepared above were compressed under a pressure of 300 bar for 1 minute, then sintered at 60 °C for 1 minute to manufacture a 3-inch diameter sputtering target.

### Examples 2 to 11

Perovskite crystals and a sputtering target were manufactured in the same manner as in Example 1, except that the manufacturing conditions were changed as shown in Table 1 below.

TABLE 1

| | MAI | PbI₂ | Good solvent | | | Antisolvent | | Crystal | |
|---|---|---|---|---|---|---|---|---|---|
| | concentration | concentration | | Volume | | | Volume | size | Yield |
| | (M) | (M) | Type | (mL) | T_{Stirring}(°C) | Type | (mL) | (inch) | (%) |
| Example 1 | 1.0 | 1.0 | GBL | 20 | 90 | CB | 15 | 1.5 | 27.4 |
| Example 2 | 1.2 | 1.2 | GBL | 20 | 90 | CB | 15 | 3 | 35.2 |
| Example 3 | 1.5 | 1.5 | GBL | 20 | 90 | CB | 15 | 3 | 34.5 |
| Example 4 | 1.8 | 1.8 | GBL | 20 | 90 | CB | 15 | 2 | 27.1 |
| Example 5 | 1.0 | 1.0 | GBL | 40 | 90 | CB | 15 | 1.5 | 58.7 |
| Example 6 | 1.0 | 1.0 | GBL | 100 | 90 | CB | 15 | 1.5 | 45.5 |
| Example 7 | 1.0 | 1.0 | GBL | 20 | 100 | CB | 15 | 1.5 | 39.6 |
| Example 8 | 1.0 | 1.0 | GBL | 20 | 110 | CB | 15 | 1.5 | 34.5 |
| Example 9 | 1.0 | 1.0 | GBL | 20 | 120 | CB | 15 | 1.5 | 36.1 |
| Example 10 | 1.0 | 1.0 | GBL | 20 | 90 | DCB | 15 | 1.5 | 23.5 |
| Example 11 | 1.0 | 1.0 | GBL | 20 | 90 | Toluene | 15 | 1.5 | 26.3 |

* T_{Stirring}: Heat treatment temperature during stirring of the precursor solution
* DCB: Dichlorobenzene

### Comparative Example 1

MAI and PbI₂ were mixed in a 1:1 molar ratio. The mixture was mechanically milled using a ball mill to prepare a composite. The milling was performed at 25 °C and 100 rpm for 10 hours. The composite was compressed under a pressure of 300 bar for 1 minute, then sintered at 60 °C for 1 minute to manufacture a 3-inch diameter sputtering target.

### Comparative Example 2

A sputtering target was manufactured in the same manner as in Comparative Example 1, except that MAI and PbI₂ were mixed in a 2:1 molar ratio.

### Comparative Example 3

The same procedure as in Example 1 was performed, except that the adding of an antisolvent was omitted. Upon examination, unlike in Example 1, crystals were not formed.

### Experimental Example 1: Confirmation of Crystal Purity

To confirm crystal purity, grazing incidence wide angle X-ray scattering (GIWAXS) analysis was performed. GIWAXS measurements were performed using Cu Ku X-rays, with rotation at 0.1° intervals in the incident angle range of 0.1° to 1.0°, and diffraction patterns were collected using a two-dimensional detector. Specifically, Rigaku SmartLab 9 kW X-ray diffraction equipment was used.

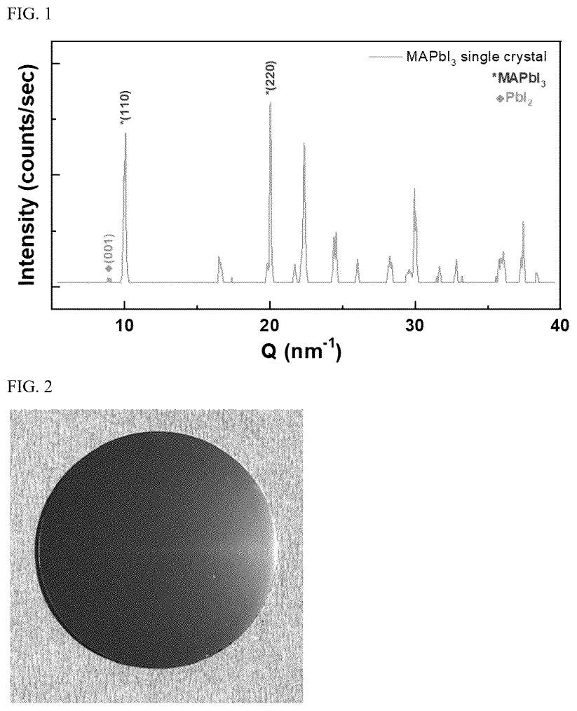

FIG. 1 is a diagram showing the GIWAXS analysis results of the perovskite crystals prepared in Example 1. Referring to this, distinct diffraction peaks were observed at scattering vectors (Q, nm⁻¹) corresponding to the (110) and (220) planes, which are major diffraction peaks of perovskite single crystals (MAPbI₃). In addition, no peaks were observed at scattering vectors corresponding to lead iodide (PbI₂). From this, it was confirmed that single-crystal MAPbI₃ was formed without phase separation into PbI₂.

In addition to Example 1, GIWAXS measurements were performed in the same manner for the perovskite crystals prepared in Examples 2 to 11 and the composite prepared in Comparative Example 1. The peak intensity at scattering vectors corresponding to the (220) plane (I_{MAPbI3}), the peak intensity at scattering vectors corresponding to lead iodide (PbI₂) (I_{PBI2}), and the ratio thereof were calculated and summarized in Table 2 below. Referring to Table 2, it was confirmed that the perovskite crystals prepared in Examples 2 to 4, like Example 1, formed single-crystal MAPbI₃ without phase separation into PbI₂. The perovskite crystals prepared in Examples 5 to 11 were confirmed to have formed with high purity with I_{PbI2}/I_{MAPbI3} values of 0.5 or less.

TABLE 2

| | I_{PbI2} | I_{MAPbI3} | I_{PbI2}/I_{MAPbI3} |
|---|---|---|---|
| Example 1 | 0 | 4750 | 0 |
| Example 2 | 0 | 5050 | 0 |
| Example 3 | 0 | 5150 | 0 |
| Example 4 | 0 | 5050 | 0 |
| Example 5 | 500 | 4550 | 0.11 |
| Example 6 | 540 | 4750 | 0.11 |
| Example 7 | 850 | 3850 | 0.22 |
| Example 8 | 810 | 4050 | 0.20 |
| Example 9 | 1200 | 4050 | 0.30 |
| Example 10 | 1200 | 2850 | 0.42 |
| Example 11 | 1000 | 2550 | 0.39 |
| Comparative | 1400 | 2150 | 0.65 |
| Example 1 | | | |

### Experimental Example 2: Confirmation of Sputtering Target Characteristics

FIG. 2 is a figure showing a sputtering target manufactured in Example 1. Referring to this, it was confirmed that the surface of the sputtering target manufactured using high-purity crystals exhibited no pores, cracks, or impurities, and was formed to be very flat and uniform. Sputtering targets with such characteristics enable stable and highly reproducible deposition processes, playing an important role in forming high-quality thin films. After mounting the sputtering target on the RF power gun of 3-inch magnetron sputtering equipment and discharging plasma, it was confirmed that stable plasma discharge was maintained.

### Experimental Example 3: Confirmation of Perovskite Thin Film Formation

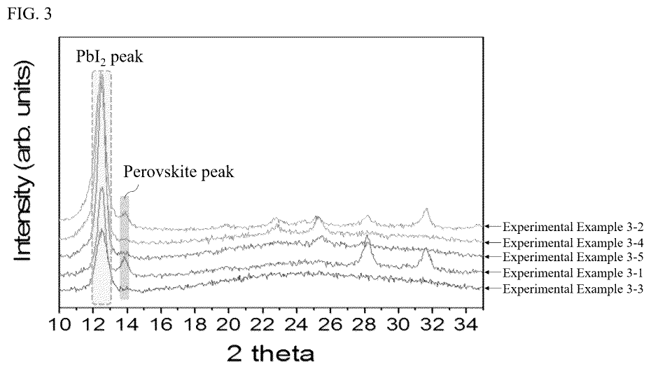

Evaporation deposition was performed using the crystals or composites prepared in the Examples and Comparative Examples. Specifically, each source material was deposited on 2.5 cm×2.5 cm glass substrates under the conditions described in the table below to form thin films. X-ray diffraction (XRD) analysis was conducted to measure the diffraction peaks of the formed thin films, and the results are shown in FIG. 3.

TABLE 3

| | | Base | | | Thin film |
|---|---|---|---|---|---|
| | Source | pressure | Current | Deposition | thickness |
| | material | (Torr) | (A) | time (sec) | (nm) |
| Experimental | Example 1 | ~10⁻⁷ | 29 | 120 | 150 |
| Example 3-1 | | | | | |
| Experimental | Example 1 | 2.0 × 10⁻⁷ | 29-30 | 89 | 208.8 |
| Example 3-2 | | | | | |
| Experimental | Example 1 | ~10⁻⁷ | 40 | 38 | 89.26 |
| Example 3-3 | | | | | |
| Experimental | Comparative | 3 × 10⁻⁷ | 29 | 80 | 175.6 |
| Example 3-4 | Example 1 | | | | |
| Experimental | Comparative | 4.9 × 10⁻⁷ | 29 | 60 | 97.6 |
| Example 3-5 | Example 2 | | | | |

Referring to FIG. 3, when deposition was performed under a current of 10 A to 35 A using the perovskite crystals prepared in the Examples, peaks identifiable as perovskite appeared. Through this, the feasibility of using the perovskite crystals prepared in the Examples as sputtering targets was confirmed.

### Experimental Example 4: Performing Sputtering Process

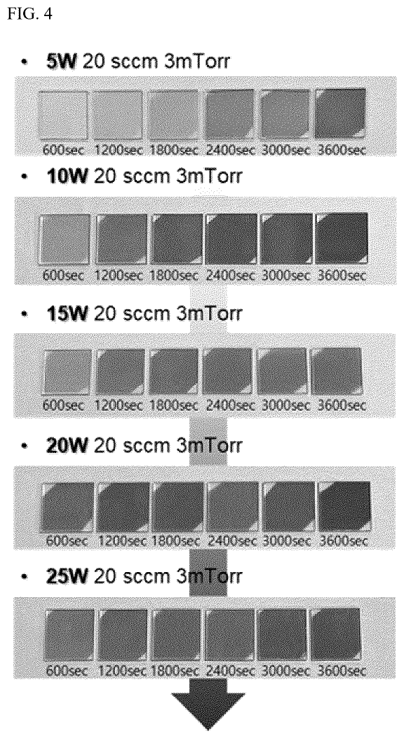

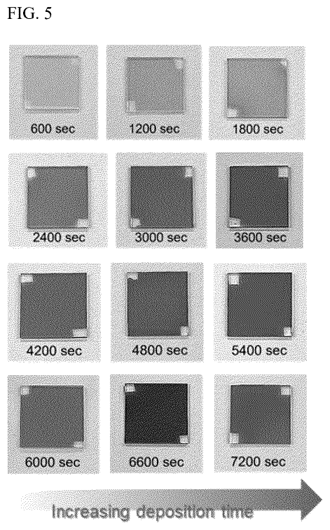

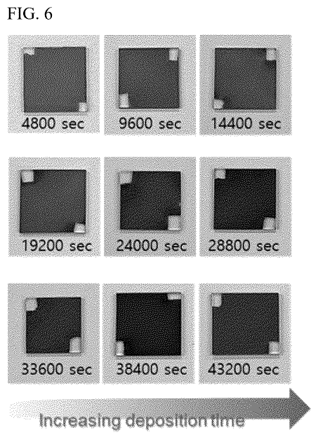

A sputtering process was performed using the sputtering target prepared in Example 1. After mounting a 1 cm×1 cm glass substrate and the sputtering target in sputtering equipment, a thin film was formed on the glass substrate by controlling the power, pressure, argon (Ar) gas flow rate, and process duration. Specifically, the Ar flow rate was set to 20 sccm, the process pressure was set to 3 mTorr, and the operating power was set to 5 W, 10 W, 15 W, 20 W, and 25 W respectively, and the sputtering process was performed for durations selected from a range of 600 seconds to 43,200 seconds. The results are shown in FIGS. 4 to 6. Referring to FIGS. 4 to 6, it can be seen that, by performing a sputtering process using a sputtering target according to an embodiment, perovskite thin films is formed under various conditions.

Although the scope of the present disclosure has been described by specific matters and limited embodiments in the present specification, the embodiments are provided only for assisting the understanding of the present disclosure more generally, and the present disclosure is not limited to the embodiments disclosed herein. Various modifications and changes is made to the embodiments by those skilled in the art to which the present disclosure pertains from the description and shall be understood as being included in the embodiments disclosed herein.

What is claimed is:

1. A method for manufacturing a sputtering target, comprising:
preparing a precursor solution comprising a metal halide, an organic halide, and a solvent;
preparing perovskite crystals by mixing the precursor solution with an antisolvent; and
sintering the perovskite crystals.

2. The method of claim 1, wherein the concentration of the metal halide or organic halide in the precursor solution is 0.9 M or more.

3. The method of claim 1, wherein the concentration of the metal halide or organic halide in the precursor solution is 1.1 M or more.

4. The method of claim 1, wherein the metal halide contains one or more divalent metal cations selected from Pb²⁺, Sn²⁺, Bi²⁺, Ge²⁺, Mn²⁺, or Cu²⁺.

5. The method of claim 1, wherein the organic halide contains one or more monovalent cations selected from methylammonium or formamidinium.

6. The method of claim 1, wherein the solvent of the precursor solution has a volume of 15 mL to 500 mL.

7. The method of claim 1, wherein the preparing a precursor solution comprises:
preparing a precursor solution by mixing a metal halide, an organic halide, and a solvent having high solubility for the metal halide and the organic halide; and
heat-treating the precursor solution.

8. The method of claim 1, wherein the antisolvent comprises one or more solvents selected from chlorobenzene, dichlorobenzene, chloroform, dichloroethylene, trichloroethylene, toluene, or xylene.

9. The method of claim 1, wherein the perovskite crystals are crystalline aggregates having an average size of 1 inch or more.

10. The method of claim 1, wherein the perovskite crystals have diffraction peaks appearing at scattering vectors (Q, nm⁻¹) corresponding to (110) and (220) planes in grazing incidence wide angle X-ray scattering (GIWAXS) analysis results using Cu Kα X-ray wavelength.

11. The method of claim 1, wherein the perovskite crystals satisfy Inequality 1 in grazing incidence wide angle X-ray scattering (GIWAXS) analysis results using Cu Kα X-ray wavelength:
I₁/I₂<0.5 [Inequality 1]
wherein in Inequality 1, I₁ is the peak intensity at a scattering vector of 9±0.5 nm⁻¹, and I₂ is the peak intensity at a scattering vector of 20.0±0.5 nm⁻¹.

12. A sputtering target manufactured by the method of claim 1.

13. A method for manufacturing a perovskite thin film, comprising performing a sputtering process using the sputtering target of claim 12.

14. The method of claim 13, wherein the sputtering process is performed under power of 4 W to 40 W.

15. The method of claim 14, wherein the sputtering process is performed for 600 seconds to 45,000 seconds.
